(19) United States
(12) Patent Application Publication
(10) Pub. No.: US 2007/0069201 A1
(43) Pub. Date: Mar. 29, 2007

(54) ORGANIC BISTABLE DEVICE AND METHOD FOR MANUFACTURING THE SAME

(76) Inventors: Chao-Feng Sung, Miaoli County (TW); Je-Ping Hu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,563

(22) Filed: Jan. 3, 2006

(30) Foreign Application Priority Data
Sep. 28, 2005 (TW) 94133684

(51) Int. Cl. H01L 29/08; H01L 29/94

(52) U.S. Cl. 257/40; 257/306; 257/E51.025

(57) ABSTRACT

An organic bistable device includes a first electrode, a second electrode, and an organic mixture layer, wherein the organic mixture layer is located between the first electrode and the second electrode. While a bias is applied between the first electrode and the second electrode of the bistable device, the doped metal material/particle is used as a mediator for injecting electrons. Therefore, both the writing/erasing cycle times and life time of an organic bistable device are increased. Moreover, the organic bistable device having an organic mixture layer with metal dopants possesses a relatively stable low conductance (off-current) state. Hence, by applying the voltage thereon, the organic bistable device can be well controlled to be turned on or turned off.

### CROSS-REFERENCE TO RELATED APPLICATION

This application claims the priority benefit of Taiwan application serial no. 94133684, filed on Sep. 28, 2005. All disclosure of the Taiwan application is incorporated herein by reference.

### BACKGROUND OF THE INVENTION

1. Field of Invention

The present invention relates to a memory device and method for manufacturing the same. More particularly, the present invention relates to an organic multi-stable device and the method for manufacturing the same.

2. Description of Related Art

In recent years, a bistable device switched between the high and low resistivity states is applied in manufacturing a memory device and On-Off switch according to different applied voltages. The material with On-Off property and memory ability includes inorganic and organic materials. It should be noted that the multi-stable memory device manufactured by applying such materials between two electrodes has got the potential of becoming a new-generation non-volatile memory device.

As for the common memory device and on-off switch, the lifetime of the device is an important technical index. The measuring technique for evaluating the lifetime of the device is endurance, i.e. writing/erasing testing. The common multi-state device only has a multi-stable layer of single material. When the device is under endurance test, its writing/erasing cycle times is only 70 and the electrical performance is unstable. Therefore, the application field of this multi-stable device is limited. In addition, during the operation of this multi-stable device with only a single multi-stable material, when a bias is applied on both ends of the multi-stable device, a multi-stable layer will bear an excessive stress due to the electric field. Accordingly, the material of the multi-stable layer may be destroyed, thereby influencing the lifetime of the device.

### SUMMARY OF THE INVENTION

The object of the present invention is to provide a multi-stable device. When under the endurance test, the writing/erasing cycle times is over 1000, approximately 10 times of that of the conventional multi-stable device.

Another object of the present invention is to provide a method for manufacturing a multi-stable device. The multi-stable device manufactured by the method according to the present invention has a stable off-current state.

An organic bistable device of the present invention comprises a first electrode, a second electrode, and an organic mixture layer, wherein the organic mixture layer is located between the first electrode and the second electrode.

In the organic bistable device according to a preferred embodiment of the present invention, a buffer layer is disposed on a surface of one of said first electrode and second electrode and contacts the organic mixture layer.

In the organic bistable device according to a preferred embodiment of the present invention, the material of said buffer layer is a material with high dielectric constant, including Al2OX, LiF, MgO, V₂O₅, or TiO2.

In the organic bistable device according to a preferred embodiment of the present invention, the material of said first electrode is copper, gold, silver, aluminium, cobalt, or nickel.

In the organic bistable device according to a preferred embodiment of the present invention, said organic mixture layer is prepared by mixing an organic material and a metal material, in which the organic material is taken as the base.

In the organic bistable device according to a preferred embodiment of the present invention, said organic material comprises Alq, AlDCN, CuPc, or the polymeric organic semiconductor materials including DH6T, DHADT, P3HT.

In the organic bistable device according to a preferred embodiment of the present invention, said metal material comprises copper, gold, silver, aluminium, cobalt, nickel, or the alloys thereof.

In the organic bistable device according to a preferred embodiment of the present invention, the ratio of the content of the organic material to that of the metal material in said organic mixture layer is about 5 to 25.

In the organic bistable device according to a preferred embodiment of the present invention, the material of said second electrode comprises coppor, gold, silver, aluminium, cobalt, or nickel.

In the organic bistable device according to a preferred embodiment of the present invention, the materials of said first and second electrodes are different.

The method for manufacturing an organic bistable device according to the present invention suitable for a substrate comprises the steps of forming a first metal layer on the substrate; then forming a buffer layer on the first metal layer; and then forming an organic mixture layer on the buffer layer; finally, forming a second metal layer on the organic mixture layer.

In the method for manufacturing an organic bistable device according to the present invention, the above method of forming an organic mixture layer comprises a step of performing the thermal evaporation process, wherein a metal material and an organic material are evaporated on the buffer layer at the same time.

In the method for manufacturing an organic bistable device according to a preferred embodiment of the present invention, the evaporation speed of said organic material is different from that of said metal material.

In the method for manufacturing an organic bistable device according to a preferred embodiment of the present invention, the ratio of the evaporation speed of said organic material to that of said metal material is about 15 to 1.

In the method for manufacturing an organic bistable device according to a preferred embodiment of the present invention, said organic material comprises Alq, AlDCN, CuPc, or polymeric organic semiconductor material including DH6T, DHADT, P3HT.

In the method for manufacturing an organic bistable device according to a preferred embodiment of the present invention, said metal material comprises copper, gold, silver, aluminium, cobalt, nickel, or the alloys thereof.

In the method for manufacturing an organic bistable device according to a preferred embodiment of the present invention, the ratio of the organic material to the metal material in the organic mixture layer is about 5 to 25.

In the method for manufacturing an organic bistable device according to a preferred embodiment of the present invention, the material of said first metal layer comprises copper, gold, silver, aluminium, cobalt, or nickel.

In the method for manufacturing an organic bistable device according to a preferred embodiment of the present invention, said buffer layer is a material with high dielectric constant including Al2OX, LiF, MgO, V₂O₅, or TiO2.

In the method for manufacturing an organic bistable device according to a preferred embodiment of the present invention, the material of the second metal layer comprises copper, gold, silver, aluminium, cobalt, or nickel.

In the method for manufacturing an organic bistable device according to a preferred embodiment of the present invention, the materials of the first and second metal layers are different.

In the method for manufacturing an organic bistable device according to a preferred embodiment of the present invention, the method for forming an organic mixture layer comprises a step of performing printing process, wherein a mixed solution is printed on the buffer layer.

In the method for manufacturing an organic bistable device according to a preferred embodiment of the present invention, said mixed solution comprises an organic solution of particles of copper, gold, silver, aluminium, cobalt, nickel, or the alloys thereof.

According to the present invention, an organic mixture layer is located between the first and second electrodes. While a bias is applied between the first and second electrodes of the bistable device, the metal material/particle doped in the organic mixture layer is used as a mediator for injecting electrons. Therefore, the writing/erasing cycle times and lifetime of an organic bistable device are increased. Moreover, the organic bistable device having an organic mixture layer with metal dopants possesses a relatively stable off-current state. Hence, by applying different voltages thereon, the organic bistable device can be well controlled to be turned on or turned off.

In order to the make the aforementioned and other objects, features and advantages of the present invention apparent, the preferred embodiments in accompany with drawings are described in detail below.

### BRIEF DESCRIPTION OF THE DRAWINGS

FIGS. 1A to 1C depict a sectional view of the method for manufacturing an organic bistable device according to a preferred embodiment of the present invention.

FIG. 2 depicts a simplified sectional view of the evaporation device used in the method for manufacturing an organic bistable device according to a preferred embodiment of the present invention.

FIG. 3A is a relationship graph of current-writing/erasing cycle times of the conventional organic bistable device.

FIG. 3B is a relationship graph of current-writing/erasing cycle times of an organic bistable device according to a preferred embodiment of the present invention.

FIG. 4A is a relationship graph of the current-voltage of a conventional organic bistable device.

FIG. 4B is a relationship graph of the current-voltage of an organic bistable device according to a preferred embodiment of the present invention.

### DESCRIPTION OF EMBODIMENTS

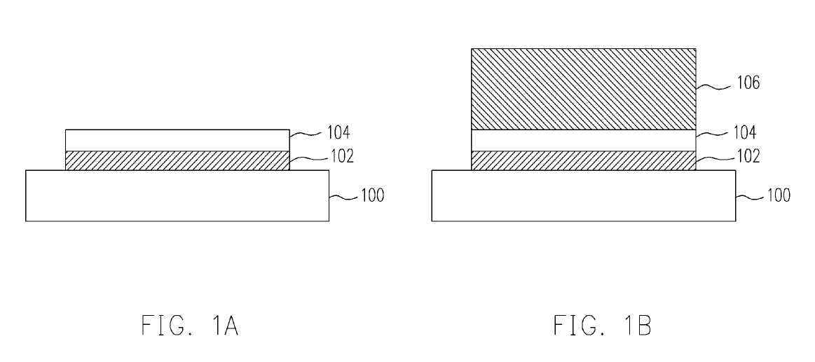

FIGS. 1A to 1C depict a sectional view of the method for manufacturing an organic bistable device according to a preferred embodiment of the present invention.

Referring to FIG. 1A, a substrate 100 is provided. A first metal layer 102 is formed on the substrate 100. The material of the first metal layer 102 comprises copper, gold, silver, aluminium, cobalt, or nickel, with the thickness of 700 Å. Then, a buffer layer 104 is formed on the first metal layer 102, wherein said buffer layer 104 is, for example, made of the material with high dielectric constant, preferably including Al2OX, LiF, MgO, V₂O₅, or TiO2. In addition, the thickness of the buffer layer 104 is about 40 Å.

Then, referring to FIG. 1B, an organic mixture layer 106 is formed on the buffer layer 104. The method for forming the organic mixture layer 106 comprises a step of performing the printing process, wherein the mixed solution containing organic material and metal material are printed on the buffer layer 104. The printing process can also be, for example, imprinting, screen printing, slot coating, silk printing, ink-jet printing, liquid toner printing, and other suitable printing process. Furthermore, the mixed solution includes an organic solution of particles of copper, gold, silver, aluminium, cobalt, nickel, or the alloys thereof. In addition, in the mixed solution, the ratio of the content of the organic material to that of the metal material is about 1 to 1000, preferably 5 to 25.

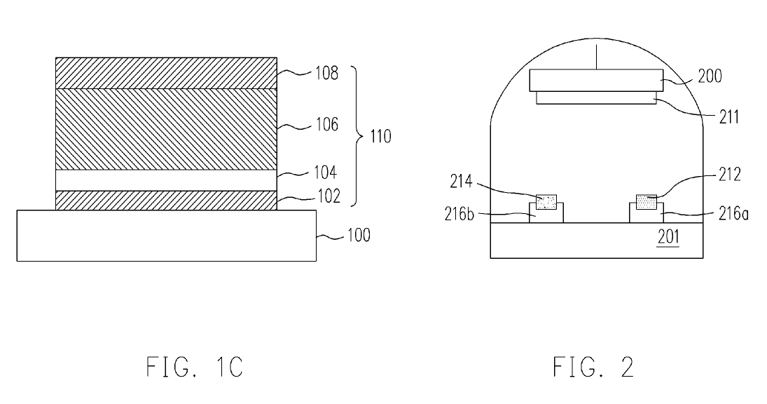

Furthermore, the preferred method for forming the organic mixture layer 106 comprises a step of performing the thermal evaporation process, wherein a metal material and an organic material are evaporated on the buffer layer 104. FIG. 2 depicts a simplified sectional view of the evaporation device used in the method for manufacturing an organic bistable device according to a preferred embodiment of the present invention. Referring to FIG. 2, in an evaporating table 210, an organic material source 212 and a metal material source 214 are disposed on the boats 216a and 216b respectively. When performing the above thermal evaporation process, the organic material source 212 and metal material source 214 carried by the boats 216a and 216b are melted and evaporated. Then, the particles of organic material and metal material are deposited on the surface of the substrate 211 on the evaporation carrier 200. In this embodiment, it should be noted that the evaporation speed of said organic material is different from that of the metal material. Preferably, the ratio of the evaporation speed of the organic material to that of the metal material is about 15 to 1. Also, in the organic mixture layer 106, the ratio of the content of the organic material to that of the metal material is about 1 to 1000, preferably 5 to 25. In addition, said organic material comprises aqueous solution, such as Alq, AlDCN, or CuPc, or polymeric organic semiconductor material including DH6T, DHADT, P3HT. The metal material comprises copper, gold, silver, aluminium, cobalt, nickel, or the alloys thereof.

Finally, referring to FIG. 1C, a second metal layer 108 is formed on the organic mixture layer 106, wherein the material of the second metal layer comprises copper, gold, silver, aluminium, cobalt, or nickel, with the thickness of about 700 Å. Thus, the manufacture of an organic bistable device 110 is accomplished. The method for forming the first metal layer 102, the buffer layer 104, and the second metal layer 108 includes evaporation and printing process, wherein the printing process includes imprinting, screen printing, slot coating, silk printing, ink-jet printing, liquid toner printing, and other suitable printing process.

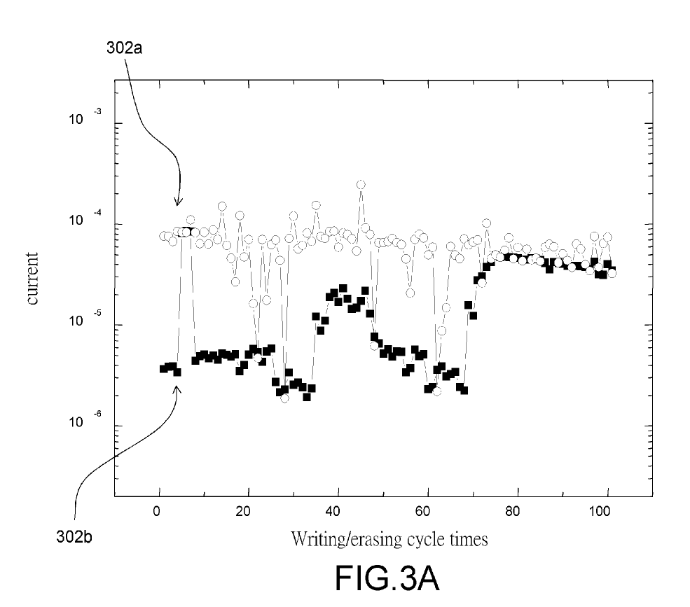

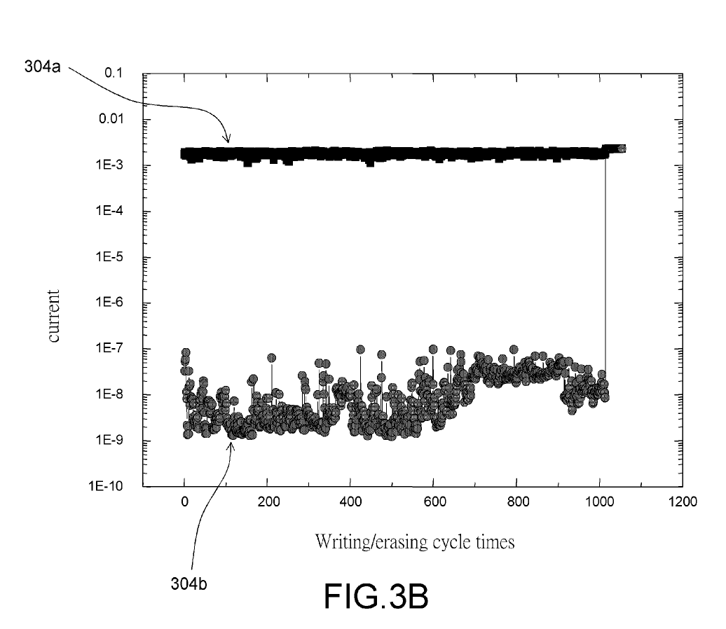

FIG. 3A is a relationship graph of the current-writing/erasing cycle times of a conventional organic bistable device. FIG. 3B is a relationship graph of the current-writing/erasing cycle times of an organic bistable device according to a preferred embodiment of the present invention. Referring to FIG. 3A, the curve 302a indicates a writing current variation curve along with the increasing of the writing/erasing cycle times, when the conventional organic bistable device is under the writing operation. Whereas the curve 302b indicates the erasing current variation curve along with the increasing of the writing/erasing cycle times, when the conventional organic bistable device is under an erasing operation. It can be seen from FIG. 3A apparently, after the writing/erasing cycle is about 70 times, the erasing current value of the conventional organic bistable device gradually shifts towards the wrting current value, and gets more and more close to the writing current value. The two values even cannot be distinguished within a single writing/erasing cycle. It indicates that the conventional organic bistable device can only bear about 70 writing/erasing cycle times in the endurance test.

Referring to FIG. 3B, the curve 304a indicates the writing current variation curve along with the increasing of the writing/erasing cycle times, when the organic bistable device of the present invention is under the writing operation. Whereas the curve 304b indicates the erasing current variation curve along with the increasing of the writing/erasing cycle times, when the organic bistable device of the present invention is under an erasing operation. Apparently, when the organic bistable device of the present invention conducts the writing/erasing cycle of about 1000 times, both of the erasing and writing current remain stable. That is, as for the organic bistable device having an organic mixture layer with doped metal material as the mediator for injecting electrons during operation, the writing/erasing cycle times of the organic bistable device can be increased to about more than ten times of that of the conventional organic bistable device, and the lifetime of the organic bistable device is also effectively increased.

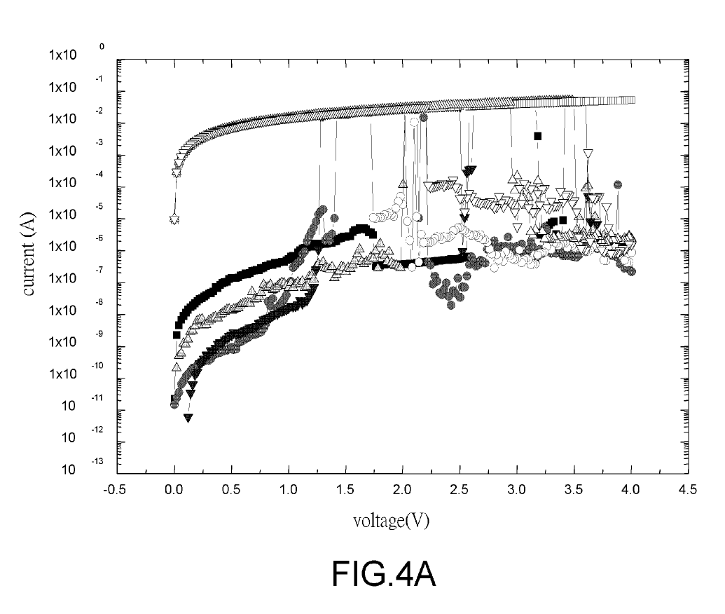

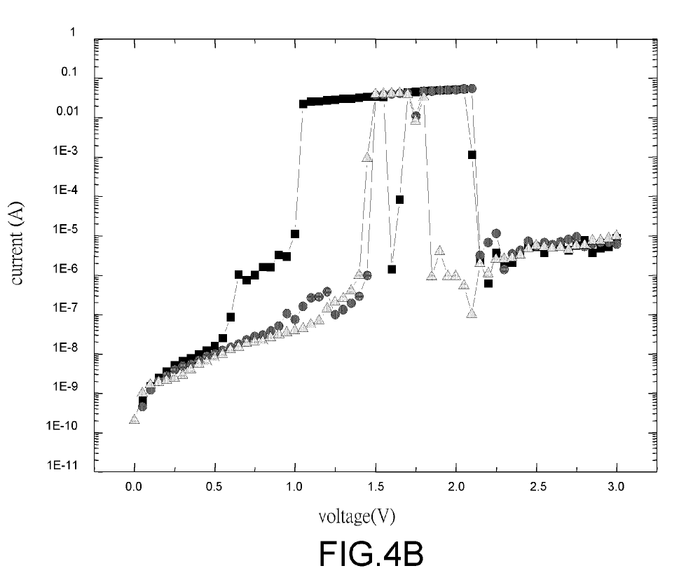

FIG. 4A is a relationship graph of the current-voltage of the conventional organic bistable device. FIG. 4B is a relationship graph of the current-voltage of the organic bistalbe device according to a preferred embodiment of the present invention. Referring to FIGS. 4A and 4B, in different reading operations, the off-current state of the conventional organic bistable device is unstable. Under the same voltage, the same organic bistble device has different currents for the off-current state. In view of the organic bistable device of the present invention, in different reading operations, under the same voltage, its current for the off-current state remains stable, i.e. the same organic bistable device has the same currents for the off-current state at each time.

In summary, according to the present invention, an organic mixture layer is located between the first and second electrodes. When a bias is applied between the first and second electrodes of the bistable device, the metal material/particle doped within the organic mixture layer is used as a mediator for injecting electrons, reducing the stress imposed onto the organic mixture layer caused by the external bias. Therefore, both the writing/erasing cycle times and lifetime of an organic bistable device are increased. Moreover, the organic bistable device having an organic mixture layer with metal dopants possesses a relatively stable off-current state. Hence, by applying different voltages thereon, the organic bistable device can be well controlled to be turned on or turned off.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An organic bistable device, comprising:
a first electrode;
a second electrode; and
an organic mixture layer located between the first electrode and the second electrode.

2. The organic bistable device as claimed in claim 1, wherein a buffer layer is disposed on a surface of one of the first and second electrodes, and contacts the organic mixture layer.

3. The organic bistable device as claimed in claim 2, wherein the material of the buffer layer is a material with high dielectric constant including Al2OX, LiF, MgO, V₂O₅, or TiO2.

4. The organic bistable device as claimed in claim 1, wherein the material of the first electrode and the material of the second electrode are respectively selected from a group consisting of copper, gold, silver, aluminium, cobalt, or nickel.

5. The organic bistable device as claimed in claim 1, wherein the organic mixture layer is prepared by mixing an organic material and a metal material.

6. The organic bistable device as claimed in claim 5, wherein the organic material comprises Alq, AlDCN, CuPc, or polymeric organic semiconductor material including DH6T, DHADT, P3HT.

7. The organic bistable device as claimed in claim 5, wherein the metal material comprises copper, gold, silver, aluminium, cobalt, nickel, or the alloys thereof.

8. The organic bistable device as claimed in claim 5, wherein in the organic mixture layer, the ratio of the content of the organic material to that of the metal material is 5 to 25.

9. The organic bistable device as claimed in claim 1, wherein the materials of the first and second electrodes are different.

10. A method for manufacturing an organic bistable device adapted to a substrate, comprising:
forming a first metal layer on the substrate;
forming a buffer layer on the first metal layer;
forming an organic mixture layer on the buffer layer; and
forming a second metal layer on the organic mixture layer.

11. The method for manufacturing an organic bistable device as claimed in claim 10, wherein the method for forming the organic mixture layer comprising:
performing a thermal evaporation, wherein a metal material and an organic material are evaporated on the buffer layer at the same time.

12. The method for manufacturing an organic bistable device as claimed in claim 11, wherein the evaporation speed of the organic material is different from that of the metal material.

13. The method for manufacturing an organic bistable device as claimed in claim 12, wherein the ratio of the evaporation speed of the organic material to that of the metal material is about 15 to 1.

14. The method for manufacturing an organic bistable device as claimed in claim 11, wherein the organic material comprises Alq, AlDCN, CuPc, or polymeric organic semiconductor material including DH6T, DHADT, P3HT.

15. The method for manufacturing an organic bistable device as claimed in claim 11, wherein the metal material comprises copper, gold, silver, aluminium, cobalt, nickel, or the alloys thereof.

16. The method for manufacturing an organic bistable device as claimed in claim 11, wherein in the organic mixture layer, the ratio of the organic material to the metal material is about 5 to 25.

17. The method for manufacturing an organic bistable device as claimed in claim 10, wherein the material of the first metal layer and the material of the second metal layer are respectively selected from a group consisting of copper, gold, silver, aluminium, cobalt, or nickel.

18. The method for manufacturing an organic bistable device as claimed in claim 10, wherein the materials of the first and second metal layer are different.

19. The method for manufacturing an organic bistable device as claimed in claim 10, wherein the method for forming the organic mixture layer comprises:
performing a printing process to print a mixed solution onto the buffer layer.

20. The method for manufacturing an organic bistable device as claimed in claim 10, wherein the mixed solution includes an organic solution of particles of copper, gold, silver, aluminium, cobalt, nickel, or the alloys thereof.
